(19) United States
(12) Patent Application Publication
(10) Pub. No.: US 2023/0163137 A1
(43) Pub. Date: May 25, 2023

(54) DRIVING THIN FILM TRANSISTOR AND DISPLAY DEVICE INCLUDING THE SAME

(71) Applicant: LG DISPLAY CO., LTD., SEOUL (KR)

(72) Inventors: Kum-Mi OH, Paju-si (KR); Deuk-Ho YEON, Paju-si (KR); Sun-Wook KO, Paju-si (KR)

(73) Assignee: LG DISPLAY CO., LTD., SEOUL (KR)

(21) Appl. No.: 17/977,368

(22) Filed: Oct. 31, 2022

(30) Foreign Application Priority Data
Nov. 22, 2021 (KR) 10-2021-0161104

(51) Int. Cl. H01L 27/12; H01L 25/16

(52) U.S. Cl. CPC H01L 27/1237; H01L 25/167

(57) ABSTRACT

A driving thin film transistor includes an insulation layer disposed on a substrate and including a first groove; a first active layer corresponding to the first groove and including a channel region and source and drain regions at both sides of the channel region; first source and first drain electrodes spaced apart from each other and being in contact with the source and drain regions, respectively; and a gate electrode overlapping the channel region, wherein the channel region is disposed on a bottom surface and inner side surfaces of the first groove, and the source and drain regions are disposed on a top surface of the insulation layer.

### CROSS-REFERENCE TO RELATED APPLICATION

The present application claims the priority of Korean Patent Application No. 10-2021-0161104 filed on Nov. 22, 2021, which is hereby incorporated by reference in its entirety.

### BACKGROUND

### Field of the Disclosure

The present disclosure relates to a driving thin film transistor and a display device including the same, and more particularly, to a driving thin film transistor that can secure more stable driving characteristics, and a display device including the same.

### Description of the Background

Recently, an LED (light emitting diode) display device using an LED as a light emitting element has been proposed. A small LED such as a mini-LED or a subminiature LED such as a micro-LED may be used for the LED display device.

A micro-LED display device is a display device that produces an image by disposing a micro-LED (µ LED) with a size of 100 micrometers or less in each pixel region and has great advantages in terms of low power consumption and downsizing.

Meanwhile, a display device necessarily needs a thin film transistor (TFT) substrate including a TFT, which is a switching element, in order to control each pixel region on/off.

Here, the LED display device requiring high performance such as a high-resolution display device requires a driving TFT to secure more stable driving characteristics in order to drive the LED, and for this purpose, research on a channel improving electron mobility has been actively conducted.

However, as the resolution of the display device increases in recent years, the size of the pixel region also decreases, and this causes a problem that the driving TFT cannot secure the required configuration of the channel.

### SUMMARY

Accordingly, the present disclosure is directed to a display device capable of realizing stable driving characteristics by securing a channel with improved electron mobility of a driving TFT.

Additional features and aspects will be set forth in the description that follows, and in part will be apparent from the description, or may be learned by practice of the present disclosure provided herein. Other features and aspects of the inventive concepts may be realized and attained by the structure particularly pointed out in the written description, or derivable therefrom, and the claims hereof as well as the appended drawings.

To achieve these and other aspects of the present disclosure, as embodied and broadly described herein, a driving thin film transistor includes an insulation layer disposed on a substrate and including a first groove; a first active layer corresponding to the first groove and including a channel region and source and drain regions at both sides of the channel region; first source and first drain electrodes spaced apart from each other and being in contact with the source and drain regions, respectively; and a gate electrode overlapping the channel region, wherein the channel region is disposed on a bottom surface and inner side surfaces of the first groove, and the source and drain regions are disposed on a top surface of the insulation layer.

The active layer may be formed of an oxide semiconductor.

The gate electrode may be disposed over the bottom surface and the inner side surfaces of the first groove and the top surface of the insulation layer.

The gate electrode may be disposed only over the bottom surface and the inner side surfaces of the first groove.

The driving thin film transistor may further include second and third active layers; second and third source electrodes being in contact with source regions of the second and third active layers, respectively; and second and third drain electrodes in contact with drain regions of the second and third active layers, respectively, wherein the insulation layer further includes second and third grooves corresponding to the second and third active layers, respectively.

The insulation layer may further include second and third grooves, wherein the channel region includes first, second, and third channel regions, and wherein the first, second, and third channel regions are disposed to correspond to the first, second, and third grooves, respectively.

The driving thin film transistor may further include a dummy region between the first, second, and third channel regions and the source and drain regions.

In another aspect of the present disclosure, a display device includes a light emitting element disposed over a substrate; and a driving thin film transistor disposed over the substrate and electrically connected to the light emitting element, wherein the driving thin film transistor includes: an insulation layer disposed on the substrate and including a first groove; a first active layer corresponding to the first groove and including a channel region and source and drain regions at both sides of the channel region; first source and first drain electrodes spaced apart from each other and being in contact with the source and drain regions, respectively; and a gate electrode overlapping the channel region, wherein the channel region is disposed on a bottom surface and inner side surfaces of the first groove, and the source and drain regions are disposed on a top surface of the insulation layer.

The light emitting element may be a micro LED.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a plan view schematically illustrating a TFT substrate of a display device according to a first aspect of the present disclosure;

FIG. 2 is an equivalent circuit diagram schematically illustrating a pixel region of FIG. 1;

FIG. 3 is a view schematically illustrating a planar structure of the driving TFTs in the pixel region of the display device according to the first aspect of the present disclosure;

FIG. 4 is a cross-sectional view taken along line IV-IV′ of FIG. 3;

FIG. 5 is a cross-sectional view taken along line V-V′ of FIG. 3;

FIG. 6A is a view illustrating a planar structure of the driving TFTs according to the background art;

FIG. 6B is a view illustrating a planar structure of the driving TFTs according to an aspect of the present disclosure;

FIG. 7 is a view schematically illustrating a planar structure of the driving TFTs in the pixel region of the display device according to another configuration of the first aspect of the present disclosure;

FIGS. 8A and 8B are views schematically illustrating a planar structure of a driving TFT in a pixel region of a display device according to a second aspect of the present disclosure; and

FIG. 9 is a view schematically illustrating a planar structure of a driving TFT in another pixel region of the second aspect of the present disclosure.

### DETAILED DESCRIPTION

Reference will now be made in detail to aspects of the disclosure, examples of which are illustrated in the accompanying drawings.

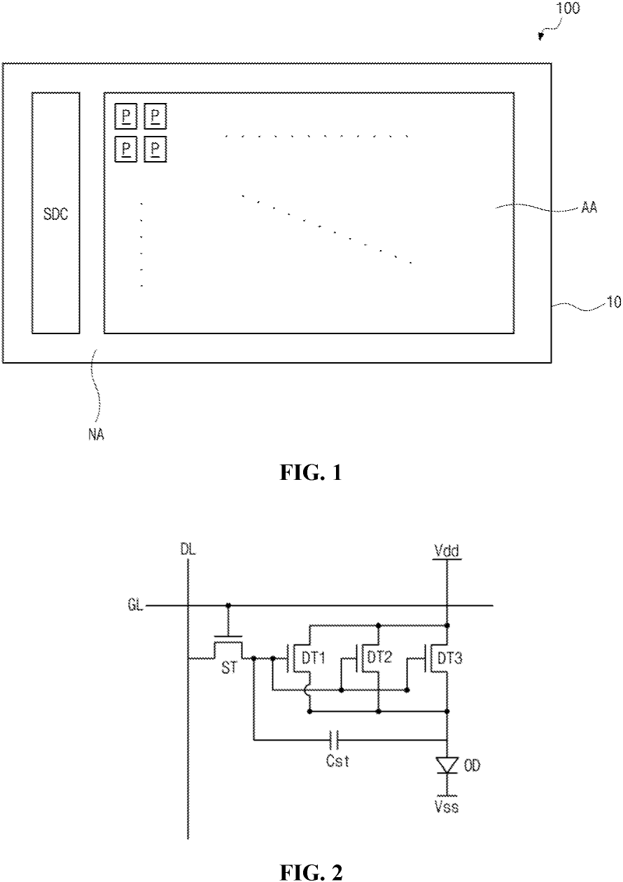

FIG. 1 is a plan view schematically illustrating a TFT substrate of a display device according to a first aspect of the present disclosure, and FIG. 2 is an equivalent circuit diagram schematically illustrating a pixel region of FIG. 1. Here, the TFT substrate may also be referred to as an array substrate.

In FIG. 1 and FIG. 2, a display area AA of as an active area for realizing an image and a non-display area NA of a non-active area surrounding the display area AA may be defined on a TFT substrate 10 of a display device 100 according to a first aspect of the present disclosure.

In the display area AA, a plurality of pixel regions P may be arranged in a matrix form. For example, the plurality of pixel regions P may include R, G, and B pixel regions P displaying red, green, and blue colors, respectively. The R, G, and B pixel regions P may be alternately arranged along one direction.

Many elements for driving the pixel region P may be formed in each pixel region P. For example, a plurality of TFTs ST, DT1, DT2, and DT3 and a light emitting element OD may be formed in each pixel region P.

In the non-display area NA, a driving circuit for driving the elements of the pixel regions P of the display area AA may be disposed. For example, a scan driving circuit SDC outputting a scan signal such as a gate signal and providing it to the pixel region P may be disposed in the non-display area NA. The scan driving circuit SDC may be directly formed on the TFT substrate 10.

The scan driving circuit SDC directly formed on the TFT substrate 10 is a so-called gate-in-panel (GIP) type driving circuit and may be formed during the manufacturing process of the TFT substrate 10, specifically, the elements in the display area AA. The GIP type scan driving circuit SDC may include a plurality of driving circuit TFTs having the same as or a similar structure to the TFTs of the pixel region P.

Referring to FIG. 2, the configuration of the pixel region P will be described in more detail. The pixel region P may include a switching TFT ST, driving TFTs DT1, DT2, and DT3, and the light emitting element OD and a storage capacitor Cst may be further provided.

The switching TFT ST may be connected to a gate line GL and a data line DL, which cross each other to define the pixel region P. For example, a gate electrode of the switching TFT ST may be connected to the gate line GL, and a drain electrode of the switching TFT ST may be connected to the data line DL.

The switching TFT ST may be turned on in response to a gate voltage applied through the gate line GL of a corresponding row line, and thus a data voltage supplied through the data line DL may be applied to the driving TFTs DT1, DT2, and DT3.

The driving TFTs DT1, DT2, and DT3 may be configured to be connected to the switching TFT ST and the light emitting element OD. For example, gate electrodes of the driving TFTs DT1, DT2, and DT3 may be electrically connected to a source electrode of the switching TFT ST, and source electrodes of the driving TFTs DT1, DT2, and DT3 may be electrically connected to the light emitting element OD.

Drain electrodes of the driving TFTs DT1, DT2, and DT3 may be configured to receive a first power voltage Vdd. Here, when the driving TFTs DT1, DT2, and DT3 are configured as N-type transistors, the first power voltage Vdd may be a high potential voltage.

As described above, the driving TFTs DT1, DT2, and DT3 control an emission current applied to the light emitting element OD according to a voltage applied to the gate electrodes, and the light emitting element OD emits light by the emission current supplied from the driving TFTs DT1, DT2, and DT3.

The light emitting element OD may be configured such that an anode electrode is connected to the source electrodes of the driving TFTs DT1, DT2, and DT3 and a cathode electrode receives a low potential voltage Vss as a second power voltage Vss.

Here, the light emitting element OD may be an organic light emitting diode (OLED), but in some cases, may be a light emitting diode (LED), a micro light emitting diode (µ LED), or the like.

The storage capacitor Cst is connected to the gate electrodes of the driving TFTs DT1, DT2, and DT3 to maintain the voltage applied thereto until the next frame. The storage capacitor Cst may be configured such that one electrode of the storage capacitor Cst is connected to the gate electrodes of the driving TFTs DT1, DT2, and DT3 and the other electrode of the storage capacitor Cst is connected to the drain electrodes or the source electrodes of the driving TFTs DT1, DT2, and DT3.

The driving TFTs DT1, DT2, and DT3 according to the first aspect of the present disclosure may be configured to be connected in parallel.

The driving TFTs DT1, DT2, and DT3 may include a first driving TFT DT1 disposed on a substrate 10, a second driving TFT DT2 disposed at one side of the first driving TFT DT1, and a third driving TFT DT3 disposed at one side of the second driving TFT DT3. Here, the first, second, and third driving TFTs DT1, DT2, and DT3 may be connected in parallel to each other and may share a gate electrode.

As described above, by connecting the plurality of driving TFTs DT1, DT2, and DT3 in parallel, the excessive inflow of the current applied to the driving TFTs DT1, DT2, and DT3 is dispersed to distribute the stress caused by the current.

That is, as the current increases, the TFT deteriorates due to the stress aggravating phenomenon caused by the current, and thus, the change in operation characteristics becomes severe. However, the driving TFTs DT1, DT2, and DT3 according to the first aspect of the present disclosure allow the excessive inflow of the current applied thereto to be dispersed while having the sufficient driving ability to drive the light emitting element OD.

Through this, the lifespan of the driving elements can be extended.

Particularly, since the display device 100 according to the aspect of the present disclosure can increase the channel widths of the driving TFTs DT1, DT2, and DT3 in the limited area of the pixel region P, the stable driving characteristics of the light emitting element OD can also be secured.

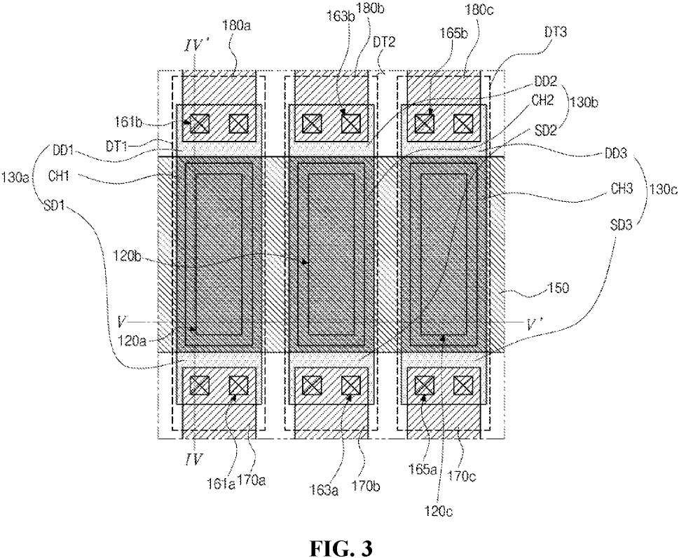

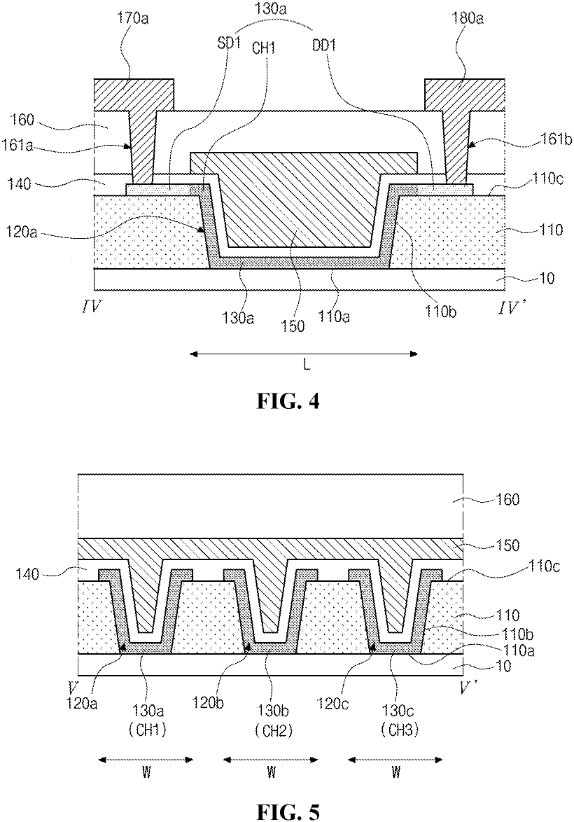

FIG. 3 is a view schematically illustrating a planar structure of the driving TFTs in the pixel region of the display device according to the first aspect of the present disclosure, FIG. 4 is a cross-sectional view taken along the line IV-IV′ of FIG. 3, and FIG. 5 is a cross-sectional view taken along the line V-V′ of FIG. 3.

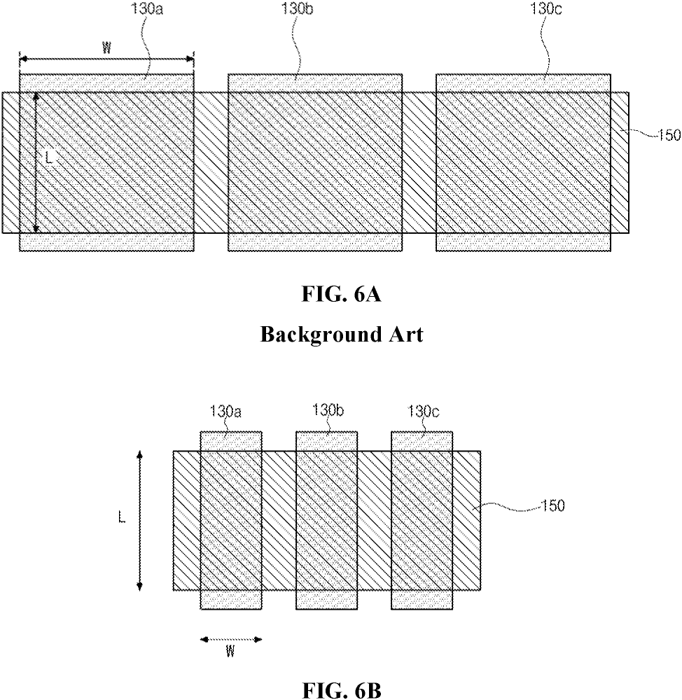

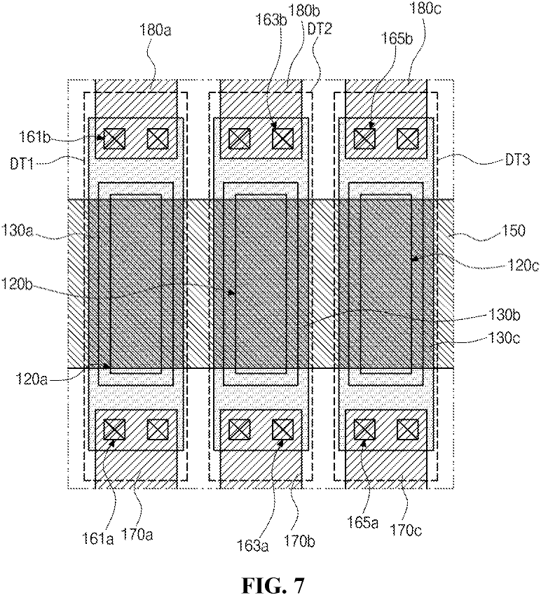

FIG. 6A is a view illustrating a planar structure of the driving TFTs according to the background art, and FIG. 6B is a view illustrating a planar structure of the driving TFTs according to the aspect of the present disclosure. FIG. 7 is a view schematically illustrating a planar structure of the driving TFTs in the pixel region of the display device according to another configuration of the first aspect of the present disclosure.

Prior to the description, for convenience of explanation, a length direction of a gate electrode 150, which is one component of the driving TFTs DT1, DT2, and DT3, is defined as a first direction, and a separation direction between source electrodes 170a, 170b, and 170c and drain electrodes 180a, 180b, and 180c, which is perpendicular to the first direction, is defined as a second direction.

In FIG. 3, the first, second, and third driving TFTs DT1, DT2, and DT3 are arranged side by side on the substrate 10. The first, second, and third driving TFTs DT1, DT2, and DT3 are spaced apart from each other along the first direction defined in the context of the figure, which is a horizontal direction.

In the first driving TFT DT1, a first source electrode 170a and a first drain electrode 180a are spaced apart from each other along the second direction defined in the context of the figure, which is a vertical direction, and a first active layer 130a is disposed in a region between the first source and first drain electrodes 170a and 180a.

In addition, the second driving TFT DT2 is disposed at one side of the first driving TFT DT1 along the first direction. In the second driving TFT DT2, a second source electrode 170b and a second drain electrode 180b are spaced apart from each other along the second direction, and a second active layer 130b is disposed between the second source and second drain electrodes 170b and 180b.

Further, the third driving TFT DT3 is disposed at one side of the second driving TFT DT2 along the first direction. In the third driving TFT DT3, a third source electrode 170c and a third drain electrode 180c are spaced apart from each other along the second direction, and a third active layer 130c is disposed between the third source and third drain electrodes 170c and 180bc.

The first, second, and third driving TFTs DT1, DT2, and DT3 are connected in parallel to each other.

The gate electrode 150 overlaps the first, second, and third active layers 130a, 130b, and 130c and is disposed along the first direction. The first, second, and third driving TFTs DT1, DT2, and DT3 share the gate electrode 150.

A first interlayer insulation layer 140 is interposed between the gate electrode 150 and the first, second, and third active layers 130a, 130b, and 130c. The first interlayer insulation layer 140 and a second interlayer insulation layer 160 are interposed between the first, second, and third active layers 130a, 130b, and 130c and the first, second, and third source electrodes 170a, 170b, and 170c and between the first, second, and third active layers 130a, 130b, and 130c and the first, second, and third drain electrodes 180a, 180b, and 180c.

The first active layer 130a is electrically connected to the first source and first drain electrodes 170a and 180a through first and second semiconductor contact holes 161a and 161b provided in the first and second interlayer insulation layers 140 and 160, respectively. The second active layer 130b is electrically connected to the second source and second drain electrodes 170b and 180b through third and fourth semiconductor contact holes 163a and 163b provided in the first and second interlayer insulation layers 140 and 160, respectively. The third active layer 130c is electrically connected to the third source and third drain electrodes 170c and 180c through fifth and sixth semiconductor contact holes 165a and 165b provided in the first and second interlayer insulation layers 140 and 160, respectively.

Here, the display device 100 of FIG. 1 according to the first aspect of the present disclosure is characterized in that an active insulation layer 110 is further provided on the substrate 10 and first, second, and third grooves 120a, 120b, and 120c are provided in the active insulation layer 110.

Although the first, second, and third grooves 120a, 120b, and 120c are shown as rectangles in a plan view, the present disclosure is not limited thereto. In another aspect, the first, second, and third grooves 120a, 120b, and 120c may be formed in various shapes such as hexagons, tetragons, triangles, circles, and the like in a plan view.

The first, second, and third grooves 120a, 120b, and 120c expose the substrate 10 through a bottom surface 110a. Inner side surfaces 110b and a top surface 110c connected to the neighboring inner side surfaces 110b are provided in the active insulation layer 110 due to the first, second, and third grooves 120a, 120b, and 120c.

The first, second, and third grooves 120a, 120b, and 120c are disposed to correspond to respective spacing regions between the first, second, and third source electrodes 170a, 170b, and 170c and the first, second, and third drain electrodes 180a, 180b, and 180c. The first, second, and third active layers 130a, 130b, and 130c are disposed to correspond to the first, second, and third grooves 120a, 120b, and 120c, respectively.

In this case, the first, second, and third grooves 120a, 120b, and 120c are formed to have smaller planar areas than the first, second, and third active layers 130a, 130b, and 130c, respectively. Thus, the first, second, and third active layers 130a, 130b, and 130c cover the inner side surfaces 110b of the first, second, and third grooves 120a, 120b, and 120c in the first, second, and third grooves 120a, 120b, and 120c, respectively and each extend to a portion of the top surface 110c of the active insulation layer 110 around the first, second, and third grooves 120a, 120b, and 120c. Namely, the first, second, and third active layers 130a, 130b, and 130c are in contact with the top surface 110c of the active insulation layer 110.

As a result, the first, second, and third active layers 130a, 130b, and 130c are formed in the first, second, and third grooves 120a, 120b, and 120c including the bottom surfaces 110a, respectively, formed on the top surface 110c of the active insulation layer 110, and formed on the inner side surfaces 110b of the first, second, and third grooves 120a, 120b, and 120c, thereby being formed three-dimensionally.

As describe above, the first, second, and third active layers 130a, 130b, and 130c are formed three-dimensionally, thereby increasing the channel width.

That is, a channel region overlapping the gate electrode 150 is defined in the first, second, and third active layer 130a, 130b, and 130c on a plane, and in the channel region, a channel length, which is a length between the source electrodes 170a, 170b, and 170c and the drain electrodes 180a, 180b, and 180c, is defined.

In addition, when a width direction substantially perpendicular to the channel length is defined, the channel width is designed to be greater than the channel length.

When the channel width is greater than the channel length, the mobility of electrons can be improved because a larger number of electrons can flow in the same time, and the driving TFTs DT1, DT2, and DT3 may have a more advantageous structure for switching a high current provided to the light emitting element OD of FIG. 2.

Accordingly, stable driving characteristics of the light emitting element OD of FIG. 2 can also be secured.

Referring to FIG. 4 and FIG. 5 in more detail, the substrate 10 supports various components of the display device 100 of FIG. 1, and the substrate 10 may be formed of glass or a plastic material having flexibility.

When the substrate 10 is formed of a plastic material, the substrate 10 may be formed of polyimide (PI), for example. In this case, the moisture component may penetrate the substrate 10 formed of polyimide (PI), and the moisture permeation may progress to the driving TFTs DT1, DT2, and DT3 or the light emitting element OD of FIG. 2, thereby deteriorating the display device 100 of FIG. 1.

Therefore, in order to prevent the performance of the display device 100 of FIG. 1 from being lowered due to the moisture permeation, the substrate 10 may be configured double polyimides. Further, an inorganic layer is formed between two polyimides, and the moisture component is blocked from passing through the lower polyimide, thereby improving the reliability of the product performance. The inorganic layer may be a single layer of silicon nitride (SiNx) or silicon oxide (SiOx) or multiple layers thereof.

The active insulation layer 110 is disposed on the substrate 10, and the first, second, and third grooves 120a, 120b, and 120c are provided in the active insulation layer 110 and spaced apart from each other. The first, second, and third active layers 130a, 130b, and 130c are disposed in the first, second, and third grooves 120a, 120b, and 120c, respectively.

Here, the first, second, and third active layers 130a, 130b, and 130c have configurations of covering the inner side surfaces 110b of the first, second, and third grooves 120a, 120b, and 120c in the first, second, and third grooves 120a, 120b, and 120c, respectively, and each being extended to the portion of the top surface 110c of the active insulation layer 110 around the first, second, and third grooves 120a, 120b, and 120c.

The first, second, and third active layers 130a, 130b, and 130c may include first, second, and third channel regions CH1, CH2, and CH3, first, second, and third source regions SD1, SD2, and SD3, and first, second, and third drain regions DD1, DD2, and DD3. Respective channels are formed in the first, second, and third channel regions CH1, CH2, and CH3 when the first, second, and third driving TFTs DT1, DT2, and DT3 are driven. The first, second, and third source regions SD1, SD2, and SD3 and the first, second, and third drain regions DD1, DD2, and DD3 are disposed at both sides of the first, second, and third channel regions CH1, CH2, and CH3, respectively.

The first, second, and third active layers 130a, 130b, and 130c may be formed of at least one selected from various metal oxides such as indium gallium zinc oxide (IGZO), indium zinc oxide (IZO), indium gallium tin oxide (IGTO), and indium gallium oxide (IGO), or the like.

The first, second, and third active layers 130a, 130b, and 130c are formed of an oxide semiconductor, so that the display device 100 of FIG. 1 according to the first aspect of the present disclosure may have high mobility and uniform characteristics.

Alternatively, the first, second, and third active layers 130a, 130b, and 130c may be formed of polycrystalline silicon (poly-Si) such as low temperature polycrystalline silicon (LTPS) and amorphous silicon (a-Si).

The first interlayer insulation layer 140 is disposed on the first, second, and third active layers 130a, 130b, and 130c. The first interlayer insulation layer 140 may be configured as a single layer of silicon nitride (SiNx) or silicon oxide (SiOx) or multiple layers thereof.

The gate electrode 150 is disposed on the first interlayer insulation layer 140 so as to overlap the channel regions CH1, CH2, and CH3 of the first, second, and third active layers 130a, 130b, and 130c. The first, second, and third driving TFTs DT1, DT2, and DT3 may share the gate electrode 150.

The gate electrode 150 may be formed of one of molybdenum (Mo), copper (Cu), titanium (Ti), aluminum (Al), chromium (Cr), gold (Au), nickel (Ni) and neodymium (Nd) or an alloy thereof and may be a single layer or multiple layers.

Here, the first, second, and third channel regions CH1, CH2, and CH3, the first, second, and third source regions SD1, SD2, and SD3, and the first, second, and third drain regions DD1, DD2, and DD3 of the first, second, and third active layers 130a, 130b, and 130c may be defined by ion doping (impurity doping). The first, second, and third channel regions CH1, CH2, and CH3 are defined by using the gate electrode 150 as a mask to block the ion doping.

Accordingly, the gate electrode 150 overlaps the first, second, and third channel regions CH1, CH2, and CH3 of the first, second, and third active layers 130a, 130b, and 130c. Therefore, the impurities are doped in the first, second, and third source regions SD1, SD2, and SD3 and the first, second, and third drain regions DD1, DD2, and DD3, and the impurities are not doped in the first, second, and third channel regions CH1, CH2, and CH3.

Then, a second interlayer insulation layer 160 is disposed on the gate electrode 150. The second interlayer insulation layer 160 may be configured as a single layer of silicon nitride (SiNx) or silicon oxide (SiOx) or multiple layers thereof.

First, second, third, fourth, fifth, and sixth semiconductor contact holes 161a, 161b, 163a, 163b, 165a, and 165b are provided in the first and second interlayer insulation layer 140 and 160. The first and second semiconductor contact holes 161a and 161b expose the first source region SD1 and the first drain region DD1 of the first active layer 130a, respectively. The third and fourth semiconductor contact holes 163a and 163b expose the second source region SD2 and the second drain region DD2 of the second active layer 130b, respectively. The fifth and sixth semiconductor contact holes 165a and 165b expose the third source region SD3 and the third drain region DD3 of the third active layer 130c, respectively. Each of the first, second, third, fourth, fifth, and sixth semiconductor contact holes 161a, 161b, 163a, 163b, 165a, and 165b may include two contact holes.

The first, second, and third source electrodes 170a, 170b, and 170c and the first, second, and third drain electrodes 180a, 180b, and 180c are disposed on the second interlayer insulation layer 160. The first, second, and third source electrodes 170a, 170b, and 170c and the first, second, and third drain electrodes 180a, 180b, and 180c are connected to the first, second, and third source regions SD1, SD2, and SD3 and the first, second, and third drain regions DD1, DD2, and DD3 of the first, second, and third active layers 130a, 130b, and 130c through the first, second, third, fourth, fifth, and sixth semiconductor contact holes 161a, 161b, 163a, 163b, 165a, and 165b.

Namely, the first source electrode 170a and the first drain electrode 180a are connected to the first source region SD1 and the first drain region DD1 of the first active layer 130a through the first and second semiconductor contact holes 161a and 161b, respectively. The second source electrode 170b and the second drain electrode 180b are connected to the second source region SD2 and the second drain region DD2 of the second active layer 130b through the third and fourth semiconductor contact holes 163a and 163b, respectively. The third source electrode 170c and the third drain electrode 180c are connected to the third source region SD3 and the third drain region DD3 of the third active layer 130c through the fifth and sixth semiconductor contact holes 165a and 165b, respectively.

The first, second, and third source electrodes 170a, 170b, and 170c and the first, second, and third drain electrode 180a, 180b, and 180c are formed of one or more of aluminum (Al), aluminum alloy such as aluminum neodymium (AlNd), copper (Cu), copper alloy, molybdenum (Mo), molybdenum titanium (MoTi), chromium (Cr), and titanium (Ti) having relatively low resistivity.

The first source electrode 170a and the first drain electrode 180a, the first active layer 130a including the first source region SD1 and the first drain region DD1 in contact with the electrodes 170a and 180a, and the gate electrode 150 disposed over the first active layer 130a constitute the first driving TFT DT1. The second source electrode 170b and the second drain electrode 180b, the second active layer 130b including the second source region SD2 and the second drain region DD2 in contact with the electrodes 170b and 180b, and the gate electrode 150 disposed over the second active layer 130b constitute the second driving TFT DT2.

The third source electrode 170c and the third drain electrode 180c, the third active layer 130c including the third source region SD3 and the third drain region DD3 in contact with the electrodes 170c and 180c, and the gate electrode 150 disposed over the third active layer 130c constitute the second driving TFT DT3.

In the display device 100 of FIG. 1 according to the first aspect of the present disclosure, the first, second, and third grooves 120a, 120b, and 120c are formed in the active insulation layer 110, and the first, second, and third active layers 130a, 130b, and 130c are disposed to correspond to the first, second, and third grooves 120a, 120b, and 120c, respectively. Specially, the first, second, and third active layers 130a, 130b, and 130c cover the inner side surfaces 110b of the first, second, and third grooves 120a, 120b, and 120c in the first, second, and third grooves 120a, 120b, and 120c of the active insulation layer 110 and extend to the portion of the top surface 110c of the active insulation layer 110 around the first, second, and third grooves 120a, 120b, and 120c, so that the channel widths of the first, second, and third active layers 130a, 130b, and 130c are widened.

More particularly, the operation characteristics of the TFTs DT1, DT2, and DT3 may be improved by increasing the mobility of electrons flowing through the active layers 130a, 130b, and 130c. The mobility is affected by the length between the source electrodes 170a, 170b, and 170c and the drain electrodes 180a, 180b, and 180c, that is, the channel length, and the channel width.

The data current I_{data} flowing the TFTs DT1, DT2, and DT3 is represented by the following Equation 1.

$$\begin{matrix}{I}_{d a t a} = \frac{1}{2} μ {C}_{o x} \frac{w}{L} {\left({V}_{g a} - {V}_{t h}\right)}^{2} \\ = \frac{1}{2} μ {C}_{o x} \frac{w}{L} {\left({V}_{d a t a} + {V}_{t h}\right)}^{2}\end{matrix}$$

Here, µ is the electron mobility of the TFTs DT1, DT2, and DT3, Cox is the capacitance of the capacitor formed by the gate electrode 150 and the channel regions CH1, CH2, and CH3 of the TFTs DT1, DT2, and DT3 per unit area, W is the width of the channel regions CH1, CH2, and CH3 of the TFTs DT1, DT2, and DT3, L is the length of the channel regions CH1, CH2, and CH3 of the TFTs DT1, DT2, and DT3, Vth is the threshold voltage of the TFTs DT1, DT2, and DT3, and Vdata is the voltage stored in the storage capacitor Cst of FIG. 2 due to the data current I_{data} provided from the data line DL of FIG. 2. In this case, µ and Cox may vary depending on the manufacturing process.

In the above-mentioned Equation 1, the data current I_{data} corresponds to the ON current flowing through the channel when the TFTs DT1, DT2, and DT3 are driven. It can be seen that the ON current is inversely proportional to the length L of the channel regions CH1, CH2, and CH3 and proportional to the width W of the channel regions CH1, CH2, and CH3.

Accordingly, if the width W of the channel regions CH1, CH2, and CH3 is large and the length L of the channel regions CH1, CH2, and CH3 is short, a greater number of electrons can flow in the same time, and thus, the mobility of electrons can be improved, so that the operation characteristics of the TFTs DT1, DT2, and DT3 can be further improved.

Therefore, in the display device 100 of FIG. 1 according to the first aspect of the present disclosure, the first, second, and third active layers 130a, 130b, and 130c are disposed to correspond to the first, second, and third grooves 120a, 120b, and 120c, respectively, so that the width W of the channel is formed wider than the length L of the channel defined on a plane.

As a result, the operation characteristics of the TFTs DT1, DT2, and DT3 are improved, and thus it is also possible to secure the stable driving characteristics of the light emitting element OD of FIG. 2.

That is, in the display device 100 of FIG. 1 according to the first aspect of the present disclosure, in order to realize the high resolution, although the size of the pixel region P of FIG. 1 is reduced and the area for the TFTs DT1, DT2, and DT3 of each pixel region P of FIG. 1 is also reduced, the channel width W of the driving TFTs DT1, DT2, and DT3 can be increased within a limited area of the pixel region P of FIG. 1.

As described above, when the channel width W is larger than the channel length L, the mobility of electrons can be improved because a larger number of electrons can flow in the same time, and thus the driving TFTs DT1, DT2, and DT3 may have a more advantageous structure for switching a high current provided to the light emitting element OD of FIG. 2.

Accordingly, the driving TFTs DT1, DT2, and DT3 can secure more stable driving characteristics, so that the stable driving characteristics of the light emitting element OD of FIG. 2 can also be secured.

FIG. 6A is a view illustrating a planar structure of driving TFTs according to the background art, and FIG. 6B is a view illustrating a planar structure of driving TFTs according to an aspect of the present disclosure. In the driving TFTs of FIGS. 6A and 6B, the first, second, and third active layers 130a, 130b, and 130c have similar channel widths W. That is, the channel width W of the first, second, and third active layers 130a, 130b, and 130c of the driving TFTs of FIG. 6B is similar to the channel width W of the first, second, and third active layers 130a, 130b, and 130c of the driving TFTs of FIG. 6A due to the grooves 120a, 120b, and 120c of FIG. 5.

Here, it can be seen that the driving TFTs of FIG. 6A requires a very large area on a plane in order to secure the channel width W. On the other hand, although the driving TFTs of FIG. 6B are implemented in a very narrow area on a plane compared to the driving TFTs of FIG. 6A, the driving TFTs of FIG. 6B can be formed to have similar channel width W of the driving TFTs of FIG. 6A because the channel width W is formed along the bottom and inner side surfaces 110a and 110b of the grooves 120a, 120b, and 120c of FIG. 5.

Accordingly, in the display device 100 of FIG. 1 according to the aspect of the present disclosure, the channel width W of the driving TFTs DT1, DT2, and DT3 can be increased in the limited area of the pixel region P of FIG. 1.

As a result, in the display device 100 of FIG. 1 according to the first aspect of the present disclosure, in order to realize the high resolution, although the size of the pixel region P of FIG. 1 is reduced and the area for the TFTs DT1, DT2, and DT3 of each pixel region P of FIG. 1 is also reduced, the channel width W of the driving TFTs DT1, DT2, and DT3 can be increased within the limited area of the pixel region P of FIG. 1, and thus the stable driving characteristics of the light emitting element OD of FIG. 2 can also be secured.

In the display device 100 of FIG. 1 according to the first aspect of the present disclosure, it is shown that the gate electrode 150 disposed across the first, second, and third active layers 130a, 130b, and 130c completely cover the first, second, and third grooves 120a, 120b, and 120c. Alternatively, as shown in FIG. 7, the gate electrode 150 may be formed to be disposed in the first, second, and third grooves 120a, 120b, and 120c of the active insulation layer 110. That is, a length of the gate electrode 150 may be shorter than a length of the grooves 120a, 120b, and 120c along a vertical direction in the context of the figure.

When the gate electrode 150 is disposed in the first, second, and third grooves 120a, 120b, and 120c, the channel width W may be partially reduced, and the channel length L can also be reduced. Accordingly, the power consumption may be further decreased, and the size of the driving TFTs DT1, DT2, and DT3 may also be reduced, thereby realizing the high resolution.

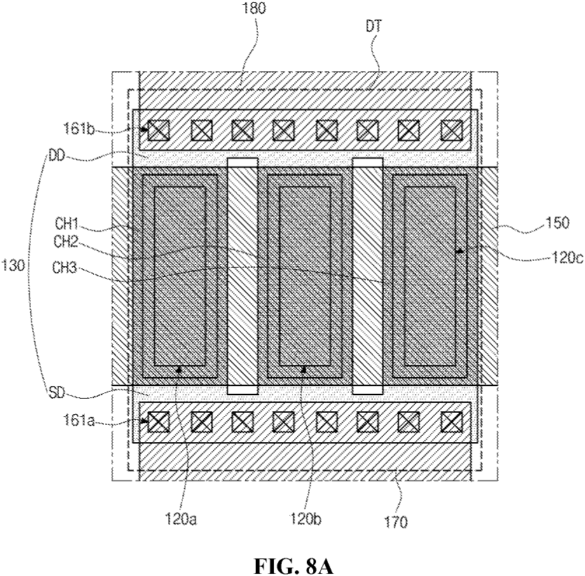

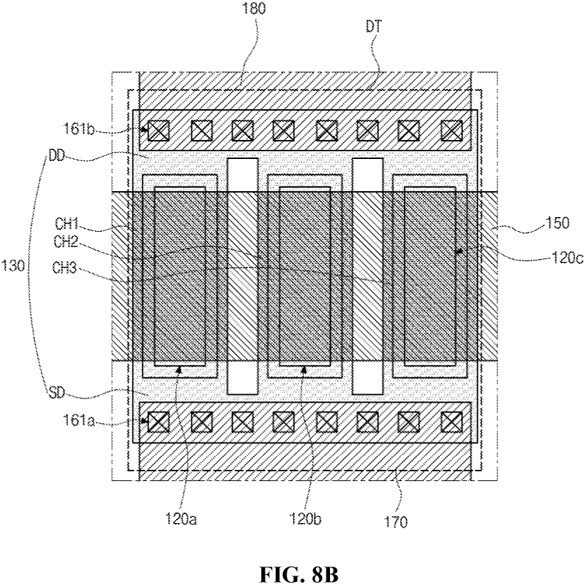

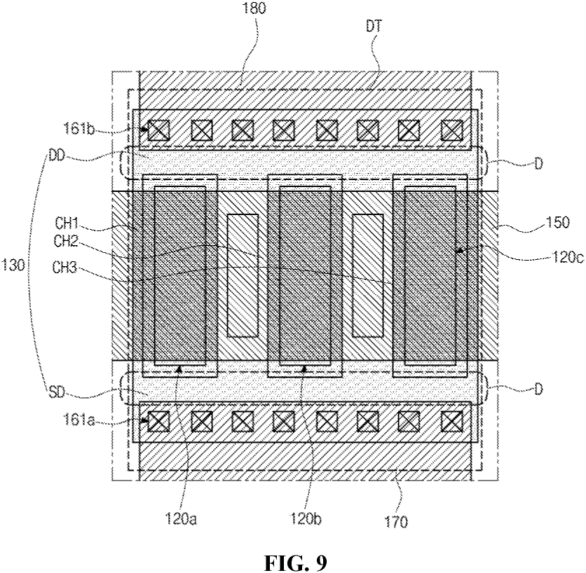

FIGS. 8A and 8B are views schematically illustrating a planar structure of a driving TFT in a pixel region of a display device according to a second aspect of the present disclosure, and FIG. 9 is a view schematically illustrating a planar structure of a driving TFT in another pixel region of the second aspect of the present disclosure.

The same reference signs are given to the same parts as those of the first aspect, and explanation for the same parts will be shortened or omitted.

While the first, second, and third driving TFTs DT1, DT2, and DT3 are provided in the first aspect, one driving TFT DT is provided in the second aspect.

As shown in the figures, an active layer 130 is disposed on the substrate 10 of FIG. 5. The active layer 130 may include source and drain regions SD and DD arranged substantially in parallel along the first direction defined in the context of the figure and the first, second, and third channel regions CH1, CH2, and CH3 spaced apart from each other and connecting the source and drain regions SD and DD along the second direction defined in the context of the figure so as to realize a multi-channel. The active layer 130 may be formed as a single body by connecting the first, second, and third active layers 130a, 130b, and 130c of FIG. 3 of the first aspect to each other and may have two openings each between adjacent two of the first, second, and third channel regions CH1, CH2, and CH3.

The gate electrode 150 is disposed on the active layer 130 with the first interlayer insulation layer 140 of FIG. 5 interposed therebetween along the second direction defined in the context of the figure. The gate electrode 150 is disposed across and overlaps the first, second, and third channel regions CH1, CH2, and CH3.

The second interlayer insulation layer 160 of FIG. 5 is disposed on the gate electrode 150, and source and drain electrodes 170 and 180 are disposed on the second interlayer insulation layer 160 of FIG. 5. The source and drain electrodes 170 and 180 are connected to the source and drain regions SD and DD of the active layer 130 exposed through the first and second semiconductor contact holes 161a and 161b provided in the first and second interlayer insulation layers 140 and 160 of FIG. 5, respectively.

Here, the display device according to the second aspect of the present disclosure is characterized in that the active insulation layer 110 of FIG. 5 is further provided on the substrate 10 of FIG. 5 and the first, second, and third grooves 120a, 120b, and 120c are provided in the active insulation layer 110 of FIG. 5.

In addition, the first, second, and third channel regions CH1, CH2, and CH3 are disposed to correspond to the first, second, and third grooves 120a, 120b, and 120c, respectively. The first, second, and third grooves 120a, 120b, and 120c are formed to have smaller planar areas than the first, second, and third channel regions CH1, CH2, and CH3, respectively. Thus, the first, second, and third channel regions CH1, CH2, and HC3 cover the inner side surfaces 110b of FIG. 5 of the first, second, and third grooves 120a, 120b, and 120c in the first, second, and third grooves 120a, 120b, and 120c, respectively and each extend to the portion of the top surface 110c of FIG. 5 of the active insulation layer 110 of FIG. 5 around the first, second, and third grooves 120a, 120b, and 120c.

As a result, the first, second, and third channel regions CH1, CH2, and CH3 are formed in the first, second, and third grooves 120a, 120b, and 120c, respectively, formed on the portion of the top surface 110c of FIG. 5 of the active insulation layer 110 of FIG. 5, and formed on the inner side surfaces 110b of FIG. 5 of the first, second, and third grooves 120a, 120b, and 120c, thereby being formed three-dimensionally.

As describe above, the first, second, and third channel regions CH1, CH2, and CH3 are formed three-dimensionally, thereby increasing the channel width W.

As shown in FIG. 8A, the gate electrode 150 overlapping the first, second, and third channel regions CH1, CH2, and CH3 may be disposed to completely cover the first, second, and third grooves 120a, 120b, and 120c of the active insulation layer 110 of FIG. 5. Alternatively, as shown in FIG. 8B, the gate electrode 150 may be formed to disposed in the first, second, and third grooves 120a, 120b, and 120c of the active insulation layer 110 of FIG. 5.

Further, as shown in FIG. 9, the active layer 130 may further include a dummy region D between the source and drain regions SD and DD and the first, second, and third channel regions CH1, CH2, and CH3.

Through this, the electric field can be distributed throughout the active layer 130, and thus it is possible to minimize the difference in the current strength for each location of the active layer 130. Accordingly, the intensity of the current output from the driving TFT DT may be more uniform, so that the luminance of light generated from the light emitting element OD of FIG. 2 may also be made more uniform.

Meanwhile, in the description so far, the driving TFTs DT1, DT2, and DT3 or the driving TFT DT has a top-gate structure. However, the present disclosure is not limited thereto, and the driving TFTs DT1, DT2, and DT3 or the driving TFT DT may have a bottom-gate structure.

Additionally, in the description so far, it has been illustrated and described that the first, second, and third driving TFTs DT1, DT2, and DT3 are connected in parallel to each other or the multi-channel is configured in one driving TFT DT. Alternatively, one driving TFT having a single channel may be provided. However, the present disclosure is not limited thereto.

Further, even when the first, second, and third driving TFTs DT1, DT2, and DT3 are connected in parallel to each other, the channel may be configured as a single channel. That is, the first, second, and third driving TFTs DT1, DT2, and DT3 may share one active layer 130. In this case, a plurality of grooves 120a, 120b, and 120c may be provided in a single channel region of the active layer 130.

As describe above, according to the present disclosure, the active insulation layer including the first, second, and third grooves is provided on the substrate, and the first, second, and third active layers disposed to correspond to the first, second, and third grooves, respectively, so that the first, second, and third active layers can have the increased the channel width.

Through this, in realizing the high resolution, although the size of the pixel region is reduced and the area for the TFT of each pixel region is also reduced, the channel width of the driving TFT can be increased within the limited area of the pixel region. Accordingly, the driving TFT can secure more stable driving characteristics, so that the stable driving characteristics of the light emitting element can also be secured.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A driving thin film transistor, comprising:
an insulation layer disposed on a substrate and including a first groove;
a first active layer corresponding to the first groove and including a channel region and source and drain regions at both sides of the channel region;
first source and first drain electrodes spaced apart from each other and respectively in contact with the source and drain regions; and
a gate electrode overlapping with the channel region,
wherein the channel region is disposed on a bottom surface and inner side surfaces of the first groove, and the source and drain regions are disposed on a top surface of the insulation layer.

2. The driving thin film transistor of claim 1, wherein the first active layer is formed of an oxide semiconductor.

3. The driving thin film transistor of claim 1, wherein the gate electrode is disposed over the bottom surface and the inner side surfaces of the first groove and the top surface of the insulation layer.

4. The driving thin film transistor of claim 1, wherein the gate electrode is disposed only over the bottom surface and the inner side surfaces of the first groove.

5. The driving thin film transistor of claim 1, further comprising:
second and third active layers;
second and third source electrodes respectively in contact with source regions of the second and third active layers; and
second and third drain electrodes respectively in contact with drain regions of the second and third active layers,
wherein the insulation layer further includes second and third grooves respectively corresponding to the second and third active layers.

6. The driving thin film transistor of claim 5, wherein the second and third active layers are formed of an oxide semiconductor.

7. The driving thin film transistor of claim 5, further comprising a first interlayer insulation layer disposed on the first active layer, the second active layer, and the third active layer.

8. The driving thin film transistor of claim 7, wherein the channel region includes first, second, and third channel regions, and
wherein the gate electrode is disposed on the first interlayer insulation layer to overlap with the first, second, and third channel regions.

9. The driving thin film transistor of claim 1, wherein the insulation layer further includes second and third grooves,
wherein the channel region includes first, second, and third channel regions, and
wherein the first, second, and third channel regions are disposed to respectively correspond to the first, second, and third grooves.

10. The driving thin film transistor of claim 1, wherein the first, second, and third grooves are provided in the insulation layer and spaced apart from each other.

11. The driving thin film transistor of claim 9, further comprising a dummy region between the first, second, and third channel regions and the source and drain regions.

12. A display device, comprising:
a light emitting element disposed over a substrate; and
a driving thin film transistor includes:
an insulation layer disposed on a substrate and including a first groove;
a first active layer corresponding to the first groove and including a channel region and source and drain regions at both sides of the channel region;
first source and first drain electrodes spaced apart from each other and respectively in contact with the source and drain regions; and
a gate electrode overlapping with the channel region,
wherein the channel region is disposed on a bottom surface and inner side surfaces of the first groove, and the source and drain regions are disposed on a top surface of the insulation layer, and
wherein the driving thin film transistor disposed over the substrate and electrically connected to the light emitting element.

13. The display device of claim 12, wherein the light emitting element is a micro LED.
